(19) United States
(12) Patent Application Publication
(10) Pub. No.: US 2026/0329408 A1
(43) Pub. Date: Oct. 22, 2026

(54) MULTIMEDIA OPERATING DEVICE

(71) Applicant: LAWO Holding AG, Rastatt (DE)

(72) Inventors: Jan HILFSDORF, Hatten (FR); Florian WEBER, Gaggenau (DE)

(73) Assignee: LAWO Holding AG, Rastatt (DE)

(21) Appl. No.: 19/694,180

(22) Filed: Jun. 1, 2026

Related U.S. Application Data
(63) Continuation of application No. PCT/EP2024/083613, filed on Nov. 26, 2024.

(30) Foreign Application Priority Data
Dec. 1, 2023 (DE) 10 2023 133 754.8

(51) Int. Cl. G06F 3/046; G06N 3/084

(52) U.S. Cl. CPC G06F 3/046; G06N 3/084

(57) ABSTRACT

A multimedia operating device for processing multimedia content via a user input. The multimedia operating device has at least one actuatable operating element with at least one magnet for receiving the user input, wherein the magnet is configured to generate a magnetic field. The multimedia operating device has at least one sensor which is assigned to the operating element and is configured to detect the magnetic field generated by the magnet and to convert the magnetic field into an electrical signal. The sensor is connected to an evaluation unit in order to transmit the electrical signal to the evaluation unit. The evaluation unit is configured to receive and evaluate the electrical signal from the sensor in such a manner that the user input is thereby registered and the multimedia content is processed.

This nonprovisional application is a continuation of International Application No. PCT/EP2024/083613, which was filed on Nov. 26, 2024, and which claims priority to German Patent Application No. 10 2023 133 754.8, which was filed in Germany on Dec. 1, 2023, and which are both herein incorporated by reference.

### BACKGROUND OF THE INVENTION

### Field of the Invention

The invention relates to a multimedia operating device for processing multimedia content via a user input.

### Description of the Background Art

Multimedia operating devices with operating elements, for example in the form of rotary controls, by means of which multimedia content can be processed, are known from the prior art. Conventionally, the rotary controls actuate electrical signal generators in the form of incremental rotary encoders, by means of which the actuation of the operating element by a user is converted into a digital electrical signal, which is then supplied to an evaluation unit for changing the desired parameter of the multimedia content. However, the electrical signal generators that are essential for these configurations occupy valuable space in the multimedia operating device, which is then no longer available for other uses. The same applies to the space requirement of the essential electrical connection between the electrical signal generators and the evaluation unit. In particular if, in order to facilitate operation, the surrounding area of the operating element is intended to be used for displaying a parameter changed by the operating element, this is not possible in the known multimedia operating devices due to the sensors and the lines assigned thereto. A disadvantage of the space requirement is, in particular, that the display of the multimedia operating device is obscured by the known operating elements.

In addition, multimedia operating devices are known that register a user input by means of a corresponding movement input on a touchscreen. However, due to the lack of haptic feedback during the user input, these multimedia operating devices are difficult and non-intuitive to operate. This disadvantage becomes particularly significant in time-critical operating situations, for example during live concerts, in which, due to the necessity for rapid inputs, the user cannot always direct the user's gaze to the multimedia operating device in order to check operation. In this respect, the cumbersome operability via touchscreen can lead to erroneous inputs.

U.S. 9 310 901 B2 discloses a multimedia device with operating elements that are provided with optical signal generators and send an optical signal to sensors arranged on the surface of the multimedia operating device. A disadvantage is that the optical transmission path between the operating element and the sensor must always be free of obstacles and is therefore susceptible to contamination. Since the sensor must continuously be in direct visual contact with the operating element, the sensor is necessarily arranged on the side of the multimedia operating device facing the operating element. This adversely affects the space available for the remaining components of the multimedia operating device. The same disadvantage is also present if a purely electrical transmission path is provided between the operating element and the sensor, since, even then, a corresponding space requirement exists on the side of the surface of the multimedia operating device assigned to the operating element.

### SUMMARY OF THE INVENTION

It is therefore an object of the present invention to eliminate the above-mentioned disadvantages from the prior art and, in particular, to develop a multimedia operating device that optimizes the space requirement of the operating elements without adversely affecting operability.

The object of the invention is achieved by a multimedia operating device that is configured for processing multimedia content via a user input and has at least one actuatable operating element for receiving the user input, wherein the operating element has at least one magnet configured to generate a magnetic field. The multimedia operating device has at least one sensor assigned to the operating element and configured to detect the magnetic field generated by the magnet and to convert the magnetic field into an electrical signal, wherein the sensor is connected to an evaluation unit in order to transmit the electrical signal to the evaluation unit. The evaluation unit is configured to receive and evaluate the electrical signal from the sensor in such a manner that the user input is thereby registered and the multimedia content is processed.

A basic concept of the invention is that, through the use of a magnetic field for transmitting the information of the user input entered via the operating element to the sensor assigned to the operating element, a simple, robust, and, in particular, wireless signal transmission is realized. Moreover, in this way it is no longer necessary to connect the sensor to the operating element assigned thereto via a cable; as a result, in particular, the necessity of forming contacts and connections between the operating element and the sensor is eliminated. Nor does the sensor need to be located in the immediate surrounding area of the operating element assigned thereto. Due to the use of the magnetic field for signal transmission, the sensor can be arranged in a manner spaced apart from the operating element assigned thereto, without an electrical line being required for transmission. This results in a considerable space saving, in particular in the environment of the operating element, and has the advantage that the surrounding area of the operating element remains usable for other purposes, for example a display assigned to the operating element. This is not possible with the known multimedia operating devices.

Within the framework of the invention, multimedia content is, for example, digital or analog audio data or video data or metadata assigned thereto.

The at least one operating element can be movable with respect to at least one spatial axis. In particular, the operating element is movable one-dimensionally or two-dimensionally.

The at least one operating element can be movable parallel and/or perpendicular to the surface of the multimedia operating device and/or rotatable about its extension direction. The operating element movable parallel to the surface of the multimedia operating device can be configured as a slide controller. The operating element movable normal to the surface of the multimedia operating device can be configured as a pushbutton and/or as a key. The operating element rotatable about its extension direction can be configured as a rotary knob. The two-dimensionally movable operating element can be configured as a planar movable slide controller or as a combination of a one-dimensional slide controller with a pushbutton. The at least one operating element can be movable continuously or between discrete positions in which it can be latched. For the movement possibilities of the operating element, a plurality of the mentioned movement types can be combinable with one another.

Preferably, at least two, in particular at least ten, in particular at least twenty operating elements can be provided, wherein at least one sensor, in particular exactly one sensor, can be assigned to each operating element. In this respect, at least two sensors can be formed. In a further development of the invention, it can be provided that the multimedia operating device has at least two display subregions to each of which at least one, in particular at least two operating elements can be assigned. Preferably, a maximum of 28 operating elements are assigned to each display subregion. The display subregions can be arranged above one another and/or adjacent to one another. For example, three display subregions, in each case comprising a maximum of 28 operating elements, are arranged adjacent to one another and above one another, thus in a 3×3 pattern. Preferably, a maximum of 28, in particular a maximum of 48, preferably a maximum of 1200 operating elements are provided.

The operating elements can be arranged in a periodic pattern, that is, at regular spacings relative to one another. The pattern can be one-dimensional or two-dimensional and, in the latter case, can have different periods in different spatial directions. In an advantageous further development of the invention, the operating elements are arranged in a rectangular pattern. Since signal transmission between the operating element and the sensor assigned thereto does not require electrical contacts and/or electrical connections, the arrangement of the operating elements on the multimedia operating device can be freely selected.

The at least one operating element can have a touch sensor for detecting a touch of the operating element by the user, wherein the touch sensor is connected, in particular, to a touch evaluation unit of the multimedia operating device. The touch sensor can be configured as a capacitive touch sensor and/or comprise an electrically conductive cap that can be arranged on the operating element. In particular, the touch sensor is connected to the touch evaluation unit via a transparent conductor track, in particular as a transparent connecting line, wherein the conductor track can be manufactured from indium tin oxide. In a further development of the invention, the touch sensor is connected wirelessly to the touch evaluation unit. In a further development of the invention, it can be provided that the evaluation unit is also configured as a touch evaluation unit. Alternatively, the touch evaluation unit can be formed separately from the evaluation unit. Further developments of the invention can provide that the touch evaluation unit is configured to detect touches on the display region, which, as stated, can be configured as a touchscreen. In this respect, the touch evaluation unit can be connected to the display region, in particular to the glass layer thereof.

The operating element can be switched into an active state or into a deactivated state depending on a signal of the touch sensor assigned to the operating element, wherein, in the active state of the operating element, user inputs can be registered and, in the deactivated state of the operating element, no user inputs can be registered. The evaluation unit can be configured in such a manner that signals of a sensor are registered and further processed only if the operating element assigned to the sensor is in an active state. As a result, it is ensured that only signals of an operating element actually touched by the user are detected and forwarded, which avoids erroneous inputs and allows for a more efficient operation of the multimedia operating device. In particular, it can be provided that the operating element is switched into the active state only if the touch sensor registers a touch of the operating element by the user. Furthermore, it can be provided that the operating element is switched into the deactivated state if the touch sensor of the operating element does not register a touch of the operating element by the user. The operating element can be configured to change at least one parameter, in particular at least two parameters, of the multimedia content.

The user input can be at least one element from the following group: Current orientation of the operating element, change of the orientation of the operating element, current position of the operating element, change of the position of the operating element.

The magnet can be configured as a permanent magnet and/or arranged in such a manner that the magnetic field generated by the magnet is aligned toward the sensor. In this respect, the magnetic field generated by the magnet can be inhomogeneous and/or anisotropic. The at least one operating element can have at least two magnets in order to allow for the actuation of the operating element by the user, and thus the user input, to be more easily detected by the sensors. Preferably, the operating element has two magnets. In a further development of the invention, the magnet is configured as a bar magnet.

The sensor can be configured as a magnetoresistive sensor, in particular as a Hall sensor, which is also referred to as a Hall transmitter or Hall probe. Within the framework of the invention, magnetoresistive sensors are sensors that detect a magnetic field by detecting an electrical resistance. Hall sensors have advantages over coils in such a way that temporally constant magnetic fields can also be detected and that, moreover, no ferromagnetic materials are required for detecting the magnetic field. Further developments of the invention can provide that the sensor is configured as an AMR sensor, in which the magnetic field can be detected by taking into consideration the anisotropic magnetic effect (AMR effect). The sensor can be formed as a giant magnetoresistance sensor, which is also referred to as a GMR sensor and in which the magnetic field is detected taking into consideration the giant magnetoresistance effect (GMR effect). The sensor can also be configured as a fluxgate sensor, which is also referred to as a fluxgate magnetometer. Alternatively or additionally, it can be provided that the sensor is configured to detect at least one, in particular at least two, preferably at least three directional components of the magnetic field generated by the magnet. The directional components of the magnetic field detected by the sensor can be storable for the subsequent evaluation of the sensor signal, in particular in the form of a vector that can be evaluated for registering the user input. In this respect, the vector of the sensor signal can serve as the basis for registering the position and/or the orientation of the operating element, for example the current rotational position or a changed rotational angle of the operating element. In this respect, the sensor can be configured for vectorial detection of the magnetic field. The electrical signal generated by the sensor can be analog or digital. The sensor can be configured to detect magnetic fields up to approximately 15 mT, in particular up to 10 mT, preferably up to 1.2 mT. At least one sensor, preferably all sensors, can be arranged on a circuit board of the multimedia operating device, which can be arranged in a region of the display region facing away from the user. The circuit board can be connected to the display region.

The multimedia operating device can have at least one display region that can be configured for reproducing information. As already stated, the display region can have at least one, in particular a plurality of display subregions. The at least one operating element can be arranged on, in or above the display region, thus in a region of the display region facing the user. In the case of a plurality of display regions, it can be provided that one display region, in particular one display subregion, is assigned to each operating element. Alternatively or additionally, it can be provided that the at least one sensor is arranged on and/or behind the display region, thus in a region of the display region facing away from the user. In an advantageous configuration of the invention, the operating element is arranged on the display region on the side facing the user and is in contact therewith. In an advantageous configuration of the invention, the at least one sensor is arranged behind the display region on the side thereof facing away from the user and/or can be in contact with the display region. In a further configuration of the invention, it can be provided that the display region is functionally divided, namely into a region facing the user, which is assigned to the operating element and the receiving of the user input, and a region facing away from the user, which is assigned to detection of the magnetic field, conversion thereof into an electrical signal and further processing thereof. The sensor can be configured separately from the display region. The magnet is preferably configured in such a manner that the magnetic field generated by the magnet penetrates the display region. At least 50%, in particular at least 75%, preferably at least 96%, most preferably the entire surface of the multimedia operating device can be configured as a display region, wherein the specifications relate to the externally visible area, which in this respect is not obscured by, in particular, the operating elements.

The display region can have a touchscreen at least in certain regions and/or be provided with a protective layer, in particular on the side facing the operating element. As a touchscreen, the display region can have a cover glass facing the user as a protective layer, a layer of glass arranged below it and a display layer. The layer of glass can have a touch sensor for detecting touches by the user. The display layer can be configured for representing graphical information. Due to the configuration of the display region as a touchscreen, receiving additional user inputs directly on the display region is simplified, which improves the operating possibilities of the multimedia operating device without simultaneously having to dispense with haptic feedback of user inputs, in the case of user inputs critical for processing the multimedia content, as a result of the actuatable operating elements. At the same time, the display region can be configured to display parameters that are intended to be changed, in particular by means of the user input. In this respect, the display region can be configured as a display having a touch function. Due to the protective layer, protection against, in particular, mechanical damage to the multimedia operating device, in particular the display region, is provided, wherein the protective layer can have a protective glass. In an advantageous further development of the invention, the entire display region is configured as a touchscreen.

Preferably, the display region can have, at least in certain regions, a display configured to display the user input registered by the operating element, in particular the parameter of the multimedia content thereby changed, in particular in the form of graphical information. The display can be configured to display a graphical representation of the operating element, for example the rotary knob, as graphical information. The display can be arranged in a surrounding area around the operating element, which improves the clarity of operation of the multimedia operating device. Preferably, the display is configured at least as part of the display layer of the touchscreen.

In particular, the multimedia operating device can have a pole plate configured to align the magnetic field generated by the magnet of the operating element toward the sensor assigned to the operating element. Preferably, at least one operating element has a pole plate, in particular if the operating element is configured as a rotary control. Further developments of the invention can provide that each operating element has a pole plate. The pole plate can be assigned to at least one sensor. This is intended, if possible, to ensure that the magnetic field generated by the magnet of the operating element reaches only the sensor assigned to the operating element. For a similar purpose, the multimedia operating device can have, in particular in the display region, at least one magnetic permeability element, in particular a permeability sheet, which is arranged, in particular, on the side of the display region facing away from the operating element in order to align the magnetic field generated by the magnet of an operating element toward the sensor assigned to the operating element. The magnetic permeability element can be arranged as a shielding sheet in the surrounding area of the sensor, in particular on the circuit board.

For example, the multimedia operating device can have at least one electromagnetic interference sensor configured to detect, in particular, electromagnetic interference influences on the magnetic field detected by the sensor. Accordingly, the interference sensor is not assigned to any operating element, but rather detects significant interference influences that, within the framework of the invention, are not attributable to a magnet of an operating element, but are caused by external sources, for example other electromagnetic transmitters, such as external permanent magnets, in particular inadequately shielded supply lines or high-voltage lines. The interference sensor can be configured to convert the detected interference influences into electrical signals and to transmit the same to the evaluation unit. In particular, the electrical signal transmitted by the sensor to the evaluation unit can be processed together with the electrical signal transmitted by the interference sensor to the evaluation unit, in order to allow for a more accurate evaluation of the user input.

The distance between the operating element and the sensor assigned thereto, in particular in a direction normal to the surface of the multimedia operating device, can be at least 16 mm. The distance between the operating element and the sensor assigned thereto can correspond to the thickness of the display region. A further significant parameter within the framework of the invention is the ratio between the distance of the operating elements relative to one another and the distance between an operating element and the sensor assigned thereto. Within the framework of the invention, an excessively small distance between the operating elements relative to one another and/or an excessively large distance between the operating element and the sensor assigned thereto can lead to sensors also detecting magnetic fields of magnets not assigned thereto when a plurality of operating elements, and thereby also a plurality of magnets in each case generating its own magnetic field, are present. This could interfere with correct registration of the user input. However, an excessively large distance is also to be avoided, since otherwise the magnetic field can no longer effectively bridge the large distance and as a result can no longer be detected by the sensor.

In particular, the evaluation unit can be configured to evaluate the received signals and to change parameters of a digital signal processing system of the multimedia operating device. In this respect, the evaluation unit can have a microcontroller or a PC and/or be connected thereto. The digital signal processing system can be configured as part of the multimedia operating device. In particular in the display region, a transparent conductor track can be arranged that connects the sensor to the evaluation unit, so that, in particular in the case of a provided display region, the user's view thereof is, if possible, not obstructed by conductor tracks. For this purpose, the conductor tracks can be manufactured from indium tin oxide. Further developments of the invention can provide that the connecting line connecting the sensor to the evaluation unit is arranged behind the display layer, thus in a region thereof facing away from the user. In the region of the display region, the connecting line can be transparent.

The evaluation unit can be configured to compensate interference fields with respect to at least one sensor. Within the framework of the invention, an interference field is a magnetic field that is detected by a sensor, but generated by a magnet other than the magnet of the operating element assigned to the sensor. If two or more operating elements are present, the magnetic fields generated by magnets of adjacent operating elements, in particular, overlap. Thus, under certain circumstances, the sensor detects not only the magnetic field generated by the operating element assigned to the sensor, but also the magnetic field of the operating element in the vicinity thereof, which in this respect is not assigned to the sensor. The evaluation unit can be configured in such a manner that compensation of the interference fields is based on all measured values of the sensors, so that, in particular with the aid of a model, the influence of interference fields on the sensors can be determined. Since this interference influence is now known, it can, for example, be subtracted from the overall received signal of the sensor, which within the framework of the invention is also referred to as the raw signal, so that only the magnetic field of the magnet of the operating element assigned to the sensor remains, which within the framework of the invention is also referred to as the pure signal. The user input can then be determined therefrom.

The evaluation unit can be configured in such a manner for compensating interference fields with respect to the sensor that the compensation is carried out on the basis of measured magnetic fields originating from at least one operating element not assigned to the sensor. In particular, it is provided that the compensation takes into consideration magnetic fields originating from magnets of all operating elements not assigned to the sensor. In the course of compensating the interference fields, it can be provided that the interference fields are determined and calculated together with, in particular subtracted from, the raw signal determined by the sensor.

Compensating the interference fields can be carried out on the basis of a model, wherein the model is dependent, in particular, on a position and/or on a movement of an operating element not assigned to the sensor and the detection of the magnetic field thereby detected by the sensor. The model can be configured in such a manner that this step is repeated successively with all operating elements not assigned to the sensor.

The model can take into consideration that an, in particular linear, relationship exists between the actually measured measurement signal of a sensor and the desired target signal actually generated by the operating element assigned to the sensor. Within the framework of the invention, the model can take into consideration that the raw signal measured by the sensor corresponds to the sum of the target signal actually to be detected and the interference signal generated, in particular, by the interference fields. Furthermore, the model can take into consideration that a linear-functional relationship exists between the interference signal of a sensor, which corresponds to the interference field of a particular operating element not assigned to the sensor, and the target signal generated by this operating element and detected by the sensor assigned to this operating element. This can be taken into consideration, in particular, for all sensors and operating elements. Preferably, the model takes into consideration a linear relationship between the target signal of a sensor, which, as stated, is generated by the operating element assigned to the sensor, and at least one raw signal detected by a sensor, in particular the raw signals of all sensors.

For compensating the interference fields, the model can provide a solution of a linear system of equations. For simplifying the compensation, the model can provide that predefined user inputs are carried out with at least one, in particular with all operating elements, for example the setting of predefined angular orientations in the case of rotary controls as operating elements.

The model can be determined before the initial commissioning of the multimedia operating device. This has the advantage that the multimedia operating device is immediately ready for use and simultaneously provides the possibility of removing influences of interference fields from the (raw) signal detected by the sensor with the aid of the model, in order to improve the accuracy of the multimedia operating device. During the operation of the multimedia operating device, the model can be unchangeable in order to obtain reproducible behavior during the compensation of the interference fields.

The evaluation unit can be configured in such a manner that the model can be changed during the operation of the multimedia operating device, in particular in the event of the movement of the operating element. As a result, the operating accuracy of the multimedia operating device can be improved. The model can provide that data of the touch sensor are used for compensation of the interference fields. The evaluation unit can be configured in such a way that a determination regarding which operating element is actuated by the user input is carried out based on the operating element that performs the greatest movement change. In a further configuration of the invention, the model can be configured analytically in order to increase process speed.

The model can be configured as a trained neural network, wherein compensation of the interference fields is carried out by forward feeding the neural network with the magnetic field detected by the sensor. A trained neural network provides the advantage of simply optimizing the compensation of interference fields for the respectively prevailing application case of the multimedia operating device and, in particular, continuously further performing the same during the commissioning thereof.

The training of the neural network can be carried out by backward feeding the neural network with the magnetic field from the operating element not assigned to the sensor. Accordingly, training data can be the raw signal detected by the sensor and the interference signal of magnets of the operating element not assigned to the sensor.

The multimedia operating device can have a multimedia processing device, in particular a mixing console. In a further configuration of the invention, the multimedia operating device can be configured as a multimedia processing device, in particular as a mixing console.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic longitudinal section through a multimedia operating device according to the invention with two operating elements and two sensors assigned thereto; and

FIG. 2 shows a further multimedia operating device in a top view.

### DETAILED DESCRIPTION

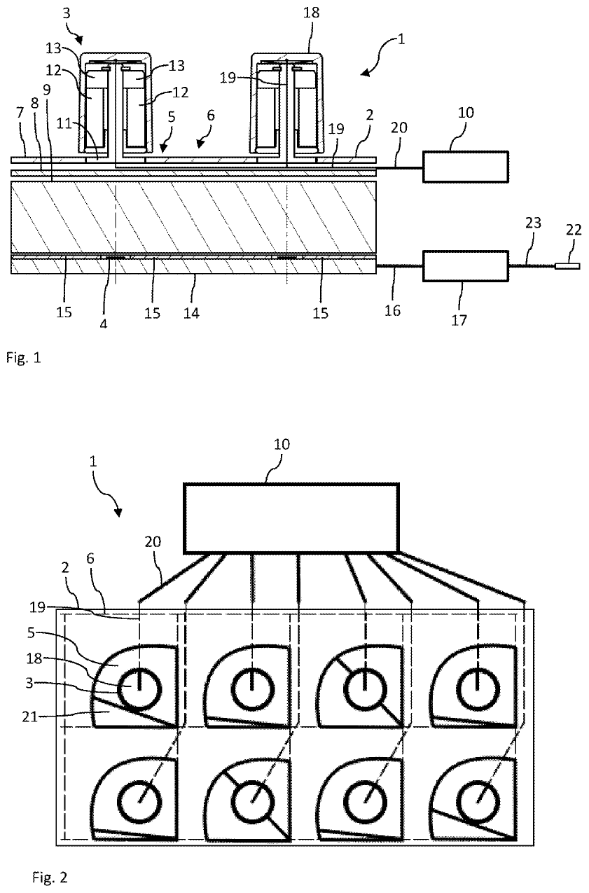

FIG. 1 shows, in a schematic side view, a multimedia operating device 1 according to the invention with a digital signal processing system not shown in FIG. 1 and with a display region 2, of which one display subregion 6 is shown. In the exemplary embodiment shown, the display region 2 is configured as a touchscreen and has a thickness of 16 mm. Viewed from top to bottom, the display region 2 has a cover glass 7 for protecting the multimedia operating device, a layer 8 of glass arranged below it and the actual display layer 9 of the touchscreen 2. The layer 8 of glass is provided with a touch sensor, not shown in FIG. 1, and in this respect is configured to detect touches of the display region 2 by the user. For this purpose, the touch sensor of the layer 8 is connected via transparent conductor tracks made of indium tin oxide, not shown in FIG. 1, to a touch evaluation unit 10 discussed further below. In this way, the signals of the touch sensor of the layer 8 are evaluated by the touch evaluation unit 10, so that user inputs on the display region 2 as a touchscreen can be detected. The display layer 9 is configured for representing graphical information 21.

On a side of the display region 2 facing the user, which points upward in FIG. 1, two operating elements 3 are in each case inserted into the display region 2 via feet 11 and connected thereto. The operating elements 3 are in each case rotatable about their extension direction and translationally movable along their extension direction, thus in each case configured as a combined rotary and push knob. The operating elements 3 in each case have two substantially axially extending bar magnets 12 that generate a magnetic field. On their side facing the user, the bar magnets 12 are provided with a pole plate 13. For reasons of clarity, these features are shown only in connection with the left operating element 3 in FIG. 1, but are also formed by the right operating element 3.

In a region of the display region 2 facing away from the operating elements 3, which points downward in FIG. 1, a circuit board 14 of the multimedia operating device 1 is arranged, on which two sensors 4 configured as Hall sensors are arranged. The sensors 4 are in each case located at the height of the operating element 3 assigned thereto. The sensors 4 are configured separately from the display region 2, but connected thereto. The distance of a sensor 4 from the operating element 3 assigned thereto, which approximately corresponds to the thickness of the display region 2, is approximately 16 mm.

Due to the arrangement of the sensors 4 relative to the operating elements 3, it is ensured that the magnetic field generated by the magnet of the operating element 3 penetrates the display region 2 of the multimedia operating device 1 and is detected by the sensor 4 assigned to the operating element 3. The sensors 4 are configured to detect the magnetic field generated by the magnet of the operating element 3 in all three spatial directions, in particular to detect a field strength of approximately 1.2 mT, so that vectorial detection of the magnetic field is carried out. For optimizing detection of the magnetic field, the sensors 4 are in each case surrounded by a shielding sheet 15. The sensors 4 convert the three detected directional components of the magnetic field into a digital electrical signal that is transmitted by means of electrical connections on the circuit board 14, not shown in FIG. 1, and by means of a connecting line 16 to an evaluation unit 17 arranged separately from the circuit board 14. The evaluation unit 17 evaluates the signals received from the sensors 4 in such a way that conclusions are drawn thereby regarding the current position and the current orientation of the operating elements 3 assigned to the sensors 4, wherein a change in the position and orientation of the operating element 3 is also detected. The position, the change in position, the orientation and the change in orientation of the operating element 3 are in each case a user input within the framework of the invention. In this respect, in the exemplary embodiment shown, both a rotational movement of the operating elements 3 and also a pressing movement are detected by the sensors 4. On this basis, the evaluation unit 17 initiates a change of a parameter of multimedia content, for example a video, that is intended to be changed by the user as a result of the user input. This is carried out by the already-mentioned digital signal processing system.

The multimedia operating device 1 according to FIG. 1 is configured to detect touches of the operating elements 3 by the user. For this purpose, the operating elements 3 are in each case provided with an electrically conductive cap 18 as a touch sensor. Upon a touch of the cap 18 by the user, an electrical signal is transmitted via a transparent electrical connecting line 19, which extends axially through the operating element 3 and the foot 11 thereof and is arranged below the cover glass 7 but above the layer 8 of glass thereon, and via a further connecting line 20 outside the layer 8 to the already-mentioned touch evaluation unit 10 and is evaluated there. Due to the transparency of the connecting line 19, in particular in the region of the layer 8, the user's view of the represented graphical information 21 of the display layer 9 remains unobstructed. The touch evaluation unit 10 is configured to activate an operating element 3 and allow for the same for input only upon a detected touch by the user. As long as the operating element 3 is not touched, the same remains deactivated so that no touch can be registered. For reasons of clarity, the features described above in connection with the touch sensor 18 are shown only with reference to the right operating element 3 in FIG. 1, but are also formed by the left operating element 3.

The display region 2 of the multimedia device according to FIG. 1 is configured in such a manner that, in a surrounding area 5 adjacent to the operating elements 3, the parameter of the multimedia content to be changed by the operating element 3 is displayed as graphical information 21. Since the display region 2 is configured as a touchscreen, the parameter assigned to the operating element 3 can be changed by a corresponding input of the user, which is likewise displayed to the user by corresponding information 21. The representation of the graphical information 21 is carried out by the display layer 9 as the display.

For detecting external magnetic fields that can interfere by overlapping with the magnetic fields of the magnets 12 to be registered, the evaluation unit 17 is connected to an interference sensor 22 arranged outside the same, the interference sensor being configured to detect these external magnetic fields and transmitting corresponding digital electrical signals to the evaluation unit 17 via an electrical connecting line.

FIG. 2 shows a further configuration of the multimedia operating device 1 with a total of eight operating elements 3, which are formed substantially analogously to the operating elements 3 of the configuration according to FIG. 1, in particular thus in each case configured as a combined rotary and push knob. In FIG. 2, the operating elements 3 are in each case arranged in and assigned to a rectangular display subregion 6. The eight display regions 6 are arranged in a two-dimensional 4×2 pattern, wherein the operating elements 3 are arranged in a manner equally spaced apart in both mutually perpendicular directions. The sensors 4 assigned to the operating elements 3 are perspectively obscured by the operating elements 3 in FIG. 2, but are nevertheless arranged, similarly to the configuration of FIG. 1, behind the operating elements 3 at the same height. For reasons of clarity, the display subregions 6 are separated from one another by dashed lines.

The view of FIG. 2 schematically shows the already-described electrical connection between the electrically conductive cap 18 as the touch sensor of the operating element 3 via the transparent electrical connecting line 18 arranged on the layer 8, which is shown dashed in FIG. 2 for reasons of clarity, and the electrical connecting line 20 outside the display region 2 with the touch evaluation unit 10. By way of example, this is shown only for the upper left operating element 3 in FIG. 2. However, each operating element is connected to the touch evaluation unit 10 with in each case a particular dedicated transparent connecting line 18 and a particular dedicated connecting line 19.

The display region 2 of the multimedia operating device 1 according to FIG. 2 is configured in such a manner that each display subregion 6 is configured in a surrounding area 5 of the operating element 3 respectively assigned to the display subregion 6 for displaying graphical information 21, wherein the graphical information 21 corresponds to the parameter changeable by the operating element 3. In the present exemplary embodiment, this is represented by a type of filling quarter circle, wherein the fill level corresponds to the currently set parameter value. If the user rotates the operating element 3 to the right, for example, the quarter circle fills, which corresponds to an increase in the parameter value, while the quarter circle empties upon rotation to the left and the parameter value is reduced. In this way, the user can recognize the currently set parameter value at a glance and, if applicable, correct the same. Thus, it is apparent from the representation of FIG. 2 that the parameter values assigned to the operating elements 3 are set differently.

The evaluation unit 17 is configured to compensate interference fields so that, on the basis of the raw signal measured by a sensor 4, the target signal to be utilized thereby, which is generated by the operating element 3 assigned to this sensor 4, is determined. The compensation is carried out based on a model that takes into consideration a linear-functional relationship between the interference field of a sensor 4 caused by a particular operating element 3 not assigned to this sensor 4 and the target signal measured by this operating element 3 at the sensor 4 assigned thereto. This consideration applies to all operating elements 3. Taking further into consideration that only the components of the magnetic fields parallel to the surface of the display region 2 are measured, compensating is therefore carried out in two-dimensional space, whereby a linear system of equations results, the solution of which can be solved analytically, in particular in the case of predefined set positions of the operating elements 3, but in any event is numerically solvable. The solution of the system of equations results in the determination of the parameters of the model. Proceeding therefrom, the target signal, thus the magnetic field generated by an operating element 3 assigned to a sensor 4 through this sensor 4, can be determined taking into consideration the measured raw signals of the sensors 4.

The model with its parameters is determined before commissioning of the multimedia operating device 1. Optionally, whether the model can be changed during commissioning or can no longer be changed can be set.

For determining the model parameters, in particular for solving the above-mentioned system of equations, the model is configured as a trained neural network, wherein compensating the interference fields is carried out by forward feeding the neural network with the magnetic field registered by the sensor 4, which within the framework of the invention is also referred to as the raw signal. Training of the neural network is carried out by backward feeding the neural network with the magnetic field of the operating element 3 not assigned to the sensor 4, thus within the framework of the invention with the interference field. In this way, compensating can be optimized, in particular during the commissioning of the multimedia operating device 1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A multimedia operating device for processing multimedia content via a user input, the multimedia operating device comprising:
at least one actuatable operating element to receive the user input, the at least one actuatable operating element having at least one magnet configured to generate a magnetic field; and
at least one sensor assigned to the at least one actuatable operating element, the at least one sensor being configured to detect the magnetic field generated by the magnet and to convert the magnetic field into an electrical signal,
wherein the at least one sensor is connected to an evaluation unit in order to transmit the electrical signal to the evaluation unit,
wherein the evaluation unit is configured to receive and evaluate the electrical signal from the sensor such that the user input is thereby registered and the multimedia content is processed.

2. The multimedia operating device according to claim 1, wherein the at least one operating element is movable with respect to at least one spatial axis.

3. The multimedia operating device according to claim 2, wherein the at least one operating element is movable substantially parallel and/or perpendicular to the surface of the multimedia operating device and/or rotatable about its extension direction.

4. The multimedia operating device according to claim 1, wherein at least two, or at least ten, or at least twenty operating elements are provided.

5. The multimedia operating device according to claim 4, wherein the operating elements are arranged in a periodic pattern.

6. The multimedia operating device according to claim 1, wherein the at least one operating element has a touch sensor to detect a touch of the operating element by the user, wherein the touch sensor is connected to a touch evaluation unit of the multimedia operating device.

7. The multimedia operating device according to claim 6, wherein the operating element is adapted to be switched into an activated state or into a deactivated state depending on a signal of the touch sensor assigned to the operating element, and wherein, in the active state of the operating element, user inputs are registered and, in the deactivated state of the operating element, no user inputs are registered.

8. The multimedia operating device according to claim 1, wherein the user input is at least one element from the following group: current orientation of the operating element, change of the orientation of the operating element, current position of the operating element, and/or change of the position of the operating element.

9. The multimedia operating device according to claim 1, wherein the magnet is configured as a permanent magnet and/or arranged in such a manner that the magnetic field generated by the magnet is aligned toward the sensor.

10. The multimedia operating device according to claim 1, wherein the sensor is configured as a magnetoresistive sensor or as a Hall sensor, and/or configured to detect at least one, or at least two, or three directional components of the magnetic field.

11. The multimedia operating device according to claim 1, wherein the multimedia operating device has a display region, wherein the at least one operating element is arranged on, in or above the display region, and/or wherein the sensor assigned to the operating element is arranged on and/or behind the display region.

12. The multimedia operating device according to claim 11, wherein the display region has a touchscreen at least in certain regions and/or is provided with a protective layer, or on the side facing the operating element.

13. The multimedia operating device according to claim 11, wherein the display region has, at least in certain regions, a display configured to display the user input registered by the operating element or display the parameter of the multimedia content thereby changed in the form of graphical information.

14. The multimedia operating device according to claim 1, further comprising at least one pole plate configured to align the magnetic field generated by the magnet of the operating element toward the sensor assigned to the operating element.

15. The multimedia operating device according to claim 1, further comprising at least one electromagnetic interference sensor configured to detect interference influences on the magnetic field detected by the sensor.

16. The multimedia operating device according to claim 1, wherein the distance between the operating element and the sensor assigned thereto, in a direction normal to the surface of the multimedia operating device, is at least 16 mm.

17. The multimedia operating device according to claim 1, wherein the evaluation unit is configured to evaluate the received signal of the sensor and to change parameters of a digital signal processing system of the multimedia operating device.

18. The multimedia operating device according to claim 1, wherein, in the display region, a transparent conductor track is arranged that connects the sensor to the evaluation unit.

19. The multimedia operating device according to claim 1, wherein the evaluation unit is configured to compensate interference fields with respect to at least one sensor.

20. The multimedia operating device according to claim 19, wherein the evaluation unit is configured in such a manner for compensating interference fields with respect to the sensor that the compensation is carried out on the basis of influences of magnets originating from at least one operating element not assigned to the sensor.

21. The multimedia operating device according to claim 19, wherein compensating the interference fields is carried out on the basis of a model, and wherein the model is dependent on a movement of an operating element not assigned to the sensor and the detection of the magnetic field thereby registered by the sensor.

22. The multimedia operating device according to claim 21, wherein the model is determined before the initial commissioning of the multimedia operating device and is unchangeable during the operation of the multimedia operating device.

23. The multimedia operating device according to claim 21, wherein the evaluation unit is configured such that the model is adapted to be changed during the operation of the multimedia operating device in the event of the movement of the operating element.

24. The multimedia operating device according to claim 21, wherein the model is configured as a trained neural network, and wherein compensating the interference fields is carried out by forward feeding the neural network with the magnetic field registered by the sensor.

25. The multimedia operating device according to claim 24, wherein training of the neural network is carried out by backward feeding the neural network with the magnetic field of the operating element not assigned to the sensor.
